(19) United States
(12) Patent Application Publication
(10) Pub. No.: US 2011/0291529 A1
(43) Pub. Date: Dec. 1, 2011

(54) BONDED GLASS CUTTING METHOD, PACKAGE MANUFACTURING METHOD, PACKAGE, PIEZOELECTRIC VIBRATOR, OSCILLATOR, ELECTRONIC DEVICE, AND RADIO-CONTROLLED TIMEPIECE

(76) Inventor: Masashi Numata, Chiba-shi (JP)

(21) Appl. No.: 13/204,344

(22) Filed: Aug. 5, 2011

Related U.S. Application Data
(63) Continuation of application No. PCT/JP2009/053337, filed on Feb. 25, 2009.

(51) Int. Cl. H01L 41/053; B26D 7/10

(52) U.S. Cl. 310/348; 83/15

(57) ABSTRACT

Provided is a bonded glass cutting method of cutting a bonded glass, in which a plurality of glass substrates is bonded together on bonding surfaces thereof through a bonding material, along an intended cutting line, the method including: a first laser irradiation step of emitting a first laser to irradiate a beam having the absorption wavelength of the bonding material along the intended cutting line to thereby delaminate the bonding material on the intended cutting line from the bonding surfaces; a second laser irradiation step of emitting a second laser to irradiate a beam having the absorption wavelength of the bonded glass along the intended cutting line to thereby form a groove on one surface of the bonded glass; and a cutting step of cutting the bonded glass along the intended cutting line by applying a breaking stress to the intended cutting line of the bonded glass.

### RELATED APPLICATIONS

This application is a continuation of PCT/JP2009/053337 filed on Feb. 25, 2009. The entire content of this application is incorporated herein by reference.

### BACKGROUND OF THE INVENTION

1. Field of the Invention

The invention relates to a bonded glass cutting method, a package manufacturing method, a package, a piezoelectric vibrator, an oscillator, an electronic device, and a radio-controlled timepiece.

2. Description of the Related Art

In recent years, a piezoelectric vibrator (package) utilizing quartz or the like has been used in mobile phones and mobile information terminals as the time source, the timing source of a control signal, a reference signal source, and the like. Although there are various piezoelectric vibrators of this type, a surface mounted device (SMD)-type piezoelectric vibrator is known as one example thereof. As a piezoelectric vibrator of this type, for example, a piezoelectric vibrator which includes a base substrate and a lid substrate which are bonded to each other, a cavity formed between the two substrates, and a piezoelectric vibrating reed (electronic component) accommodated in a state of being airtightly sealed in the cavity is known.

When the piezoelectric vibrator is manufactured, cavity recesses are formed on a lid substrate wafer, and a piezoelectric vibrating reed is mounted on a base substrate wafer. Thereafter, the two wafers are anodically bonded with a bonding layer disposed therebetween, thus obtaining a wafer assembly in which a plurality of packages is formed in the matrix direction of the wafers. Then, the wafer assembly is cut into the respective packages (cavities) formed on the wafer assembly, whereby a plurality of piezoelectric vibrators (packages) in which the piezoelectric vibrating reed is airtightly sealed in the cavity is manufactured.

As a method of cutting the wafer assembly, there is known a method in which the wafer assembly is cut (diced) along its thickness direction using a diamond-tipped blade, for example.

However, the blade cutting method has the following problems. Since it is necessary to provide a cutting zone between the cavities taking the width of the blade into account, the number of piezoelectric vibrators obtainable from one wafer assembly is small. In addition, the blade cutting method produces chipping during cutting, and the cutting surface is coarse. Moreover, another problem is poor production efficiency due to its low processing speed.

There is known another cutting method in which a cut (scribe line) is inscribed along the intended cutting line on the surface of the wafer assembly using diamond embedded in the tip end of a metal rod, and the wafer assembly is cut by applying a breaking stress along the scribe line.

However, since the above-described method produces significant chipping on the scribe line, there is a problem in that the wafer is likely to break, and the surface precision of the cutting surface is coarse.

In order to solve the above-mentioned problems, a method of cutting the wafer assembly using a laser has been developed. As an example of such a method, Patent Citation 1 discloses a method in which a laser beam is irradiated with a focusing point at the inside of a wafer assembly, and a modified region through multiphoto absorption is formed along the intended cutting line of the wafer assembly. Moreover, the wafer assembly is cut along the modified region as the starting point by applying a breaking stress (impact force) to the wafer assembly.
Patent Citation 1: Japanese Patent No. 3408805

However, in the configuration of Patent Citation 1, a number of laser pulse marks are formed inside the wafer assembly, and the pulse marks become a damaged layer which remains inside the wafer assembly. Moreover, stress is concentrated on the damaged layer, and there is a problem in that cracks form in the surface direction of the wafer assembly when cutting the wafer assembly. Another problem is that mechanical durability of a piezoelectric vibrator which is formed after the cutting of the wafer assembly decreases.

In addition, as described above, although the wafer assembly is formed by anodically bonding the wafers using a bonding layer, it is necessary to apply a voltage to the entire bonding layer at once when bonding the wafers. Therefore, it is necessary that the bonding layer is formed to be continuous on the bonding surface of the wafer assembly. Moreover, when the wafer assembly is to be cut in a state where the bonding layer is formed to be continuous on the bonding surface, namely in a state where the bonding layer is connected between the respective piezoelectric vibrators, the progress of cracking in the thickness direction of the wafer assembly during breaking may be impaired. Thus, there is a problem in that cracks or the like form in the surface direction of the wafer assembly, and it is difficult to cut the wafer assembly to the desired size for each piezoelectric vibrator.

As a result, there is a problem in that in the worst case, the cavity may communicate with the outside, thus making it unable to maintain the airtightness in the cavity. Such a product will be treated as defective, therefore, there is a problem in that the number of non-defective products picked out of the wafer assembly decreases and the yield decreases.

### SUMMARY OF THE INVENTION

The invention has been made in view of the above problems, and an object of the invention is to provide a bonded glass cutting method capable of improving yield by cutting a bonded glass into a predetermined size. Another object of the invention is to provide a package manufacturing method, a package, a piezoelectric vibrator, an oscillator, an electronic device, and a radio-controlled timepiece.

The invention provides the following means in order to solve the problems.

According to an aspect of the invention, there is provided a bonded glass cutting method of cutting a bonded glass, in which a plurality of glass substrates is bonded together on bonding surfaces thereof through a bonding material, along an intended cutting line, the method including: a first laser irradiation step of emitting a first laser to irradiate a beam having the absorption wavelength of the bonding material along the intended cutting line to thereby delaminate the bonding material on the intended cutting line from the bonding surfaces; a second laser irradiation step of emitting a second laser to irradiate a beam having the absorption wavelength of the bonded glass along the intended cutting line to thereby form a groove on one surface of the bonded glass; and a cutting step of cutting the bonded glass along the intended cutting line by applying a breaking stress to the intended cutting line of the bonded glass.

According to this configuration, after the groove is formed along the intended cutting line on the surface layer portion of the glass substrate before the cutting step, by applying a breaking stress along the intended cutting line, it is possible to cut the bonded glass. In this case, it is possible to provide merits such as, for example, a very small cutting zone, a high cutting speed, good surface precision of the cutting surface, and less chipping, as compared to the blade cutting method of the related art. Moreover, since there is no possibility of forming a damaged layer inside the bonded glass, no crack will be formed in the surface direction of the bonded glass when cutting the bonded glass, and the mechanical durability of the bonded glass after cutting will not decrease.

In particular, by delaminating the bonding material on the intended cutting line before the second laser irradiation step, it is possible to facilitate the progress of cracking in the thickness direction of the bonded glass during cutting and to prevent the progress of cracking in the surface direction of the bonded glass. Therefore, the bonded glass is smoothly cut along the intended cutting line. As a result, it is possible to improve surface precision of the cutting surface and to prevent breaking or the like of the bonded glass during cutting, thus cutting the bonded glass to a desired size.

In addition, the bonding material may be made of a conductive metallic material, the bonded glass may have a plurality of glass substrates of which the bonding surfaces are anodically bonded to each other, and in the first laser irradiation step, the wavelength of the first laser may be set to 532 nm.

According to this configuration, by anodically bonding the glass substrates through a metallic material, it is possible to prevent positional shift due to aging or impact and warping or the like of the bonded glass, and to bond the glass substrates more tightly as compared to the case of bonding the glass substrates through an adhesive agent or the like.

In particular, when the first laser having a wavelength of 532 nm is used in the first laser irradiation step, since all the output of the laser beam is absorbed by the bonding material to heat the bonding material, the bonding material is melted quickly, and the bonding material in the irradiation region of the laser beam is contracted toward the outer side from the irradiation region of the laser beam. Therefore, it is possible to delaminate the bonding material on the intended cutting line effectively.

In addition, the glass substrate may be formed of a soda-lime glass, and in the second laser irradiation step, the wavelength of the second laser may be set to 266 nm.

According to this configuration, by irradiating the glass substrate formed of a soda-lime glass with the second laser having a wavelength of 266 nm, the laser beam is entirely absorbed in the surface layer portion of the bonded glass. Thus, it is possible to form a desired groove on the surface layer portion of the bonded glass. That is, since it is possible to form the groove having good linearity with less chipping and debris, the bonded glass can be cut to a desired size in a subsequent cutting step.

In addition, in the cutting step, the breaking stress may be applied along the groove from the other surface of the bonded glass.

According to this configuration, by applying the breaking stress along the groove from the other surface of the bonded glass, since it is possible to cut the bonded glass in a smooth and easy manner, it is possible to obtain a cutting surface having better surface precision.

In addition, the bonded glass may be bonded by disposing the bonding material on only a part of the intended cutting line, and in the first laser irradiation step, the beam of the first laser may be irradiated onto only the bonding material disposed on the intended cutting line.

According to this configuration, in the first laser irradiation step, it is possible to decrease the area of the bonding material delaminated by the first laser. As a result, it is possible to shorten the time for the first laser irradiation step and to improve workability.

According to another aspect of the invention, there is provided a method of manufacturing a package which includes a plurality of glass substrates bonded to each other through a bonding material and a cavity formed at the inner side of the plurality of glass substrates, and which is capable of sealing an electronic component in the cavity, wherein the plurality of glass substrates is cut for each formation region of the package using the bonded glass cutting method according to the above aspect of the invention.

According to this configuration, by cutting the glass substrates using the bonded glass cutting method according to the above aspect of the invention, it is possible to facilitate the progress of cracking in the thickness direction of the bonded glass during cutting and to prevent the progress of cracking in the surface direction of the bonded glass. Therefore, the glass substrates can be smoothly cut along the intended cutting line of each package formation region during cutting. As a result, it is possible to improve the surface precision of the cutting surface and to prevent cracking or the like of the glass substrates during cutting, thus cutting the glass substrates to a desired size.

As a result, it is possible to secure airtightness in the cavity and to provide a package having high reliability. Therefore, it is possible to increase the number of packages picked out as non-defective products and to improve yield.

According to a further aspect of the invention, there is provided a package which includes a plurality of glass substrates bonded to each other through a bonding material and a cavity formed at an inner side of the plurality of glass substrates, and in which an electronic component is sealed in the cavity, wherein the package is cut using the bonded glass cutting method according to the above aspect of the invention, and wherein a chamfered portion where the groove formed by the second laser is divided is provided on an outer peripheral portion of a surface of the package on a side where it is irradiated by the second laser.

According to this configuration, even when a mechanism for picking out the package comes into contact with the corners of the package when the cut packages are picked out, since it is possible to suppress generation of chipping, the packages can be picked out as non-defective products.

The chamfered portions can be formed automatically by cutting the bonded glass along the groove (intended cutting line) after forming the groove through the second laser irradiation. Therefore, it is possible to form the chamfered portions more quickly and easily compared with the case of forming the chamfered portions in the respective cut packages. As a result, it is possible to improve workability.

In addition, by cutting the bonded glass along the groove, it is possible to improve the surface precision of the cutting surface of the package and provide a package having high reliability.

According to a still further aspect of the invention, there is provided a piezoelectric vibrator in which a piezoelectric vibrating reed is airtightly sealed in the cavity of the package according to the above aspect of the invention.

According to this configuration, it is possible to provide a piezoelectric vibrator which secures airtightness in the cavity and provides excellent vibration properties.

According to a still further aspect of the invention, there is provided an oscillator in which the piezoelectric vibrator according to the above aspect of the invention is electrically connected to an integrated circuit as an oscillating piece.

According to a still further aspect of the invention, there is provided an electronic device in which the piezoelectric vibrator according to the above aspect of the invention is electrically connected to a clock section.

According to a still further aspect of the invention, there is provided a radio-controlled timepiece in which the piezoelectric vibrator according to the above aspect of the invention is electrically connected to a filter section.

In the oscillator, electronic device, and radio-controlled timepiece according to the above aspect of the invention, since they have the above-described piezoelectric vibrator, it is possible to provide products having high reliability similarly to the piezoelectric vibrator.

According to the bonded glass cutting method according to the above aspect of the invention, by delaminating the bonding material on the intended cutting line before the second laser irradiation step, it is possible to facilitate the progress of cracking in the thickness direction of the bonded glass during cutting and to prevent the progress of cracking in the surface direction of the bonded glass. Therefore, the bonded glass is smoothly cut along the intended cutting line. As a result, it is possible to improve surface precision of the cutting surface and to prevent breaking or the like of the bonded glass during cutting, thus cutting the bonded glass to a desired size.

According to the package manufacturing method and the package according to the above aspect of the invention, since the package is manufactured using the bonded glass cutting method according to the above aspect of the invention, it is possible to secure airtightness in the cavity and provide a package having high reliability. Therefore, it is possible to increase the number of packages picked out as non-defective products and thus to improve yield.

According to the piezoelectric vibrator according to the above aspect of the invention, it is possible to provide a piezoelectric vibrator which secures airtightness in the cavity and provides excellent vibration properties.

According to the oscillator, electronic device, and radio-controlled timepiece according to the above aspect of the invention, since they have the above-described piezoelectric vibrator, it is possible to provide products having high reliability similarly to the piezoelectric vibrator.

### BRIEF DESCRIPTION OF DRAWINGS

FIG. 1 is a perspective view showing an external appearance of a piezoelectric vibrator according to an embodiment of the invention.

FIG. 2 is a plan view showing an inner structure of the piezoelectric vibrator shown in FIG. 1 when a piezoelectric vibrating reed is viewed from above with the lid substrate removed.

FIG. 3 is a cross-sectional view of the piezoelectric vibrator taken along the line A-A in FIG. 2.

FIG. 4 is an exploded perspective view of the piezoelectric vibrator shown in FIG. 1.

FIG. 5 is a flowchart showing the flow of the process of manufacturing the piezoelectric vibrator shown in FIG. 1.

FIG. 6 is an exploded perspective view showing one step of the process of manufacturing the piezoelectric vibrator in accordance with the flowchart shown in FIG. 5, showing a wafer assembly in which the base substrate wafer and the lid substrate wafer are anodically bonded with the piezoelectric vibrating reed accommodated in the cavity.

FIG. 7 is a flowchart showing the flow of a fragmentation step.

FIG. 8 is a cross-sectional view of the wafer assembly, illustrating the fragmentation step.

FIG. 9 is a cross-sectional view of the wafer assembly, illustrating the fragmentation step.

FIG. 10 is a cross-sectional view of the wafer assembly, illustrating the fragmentation step.

FIG. 11 is a cross-sectional view of the wafer assembly, illustrating the fragmentation step.

FIG. 12 is a cross-sectional view of the wafer assembly, illustrating the fragmentation step.

FIG. 13 is a cross-sectional view of the wafer assembly, illustrating the fragmentation step.

FIG. 14 is a plan view illustrating a trimming step, showing a base substrate wafer of the wafer assembly with a lid substrate wafer removed.

FIG. 15 is a graph showing the relationship between wavelength (nm) and transmittance (%).

FIG. 16 is a view showing the state of a bonding layer when a trimming line is formed using a YAG laser during a first laser selection test.

FIG. 17 is a view showing the state of a bonding layer when a trimming line is formed using a second-harmonic laser during the first laser selection test.

FIG. 18 is a view showing the configuration of an oscillator according to an embodiment of the invention.

FIG. 19 is a view showing the configuration of an electronic device according to an embodiment of the invention.

FIG. 20 is a view showing the configuration of a radio-controlled timepiece according to an embodiment of the invention.

FIG. 21 is a plan view illustrating a patterning step according to another configuration of the present embodiment, showing a base substrate wafer of a wafer assembly with a lid substrate wafer removed.

### DETAILED DESCRIPTION OF THE PREFERRED EMBODIMENTS

Hereinafter, an embodiment of the invention will be described with reference to the drawings.

### (Piezoelectric Vibrator)

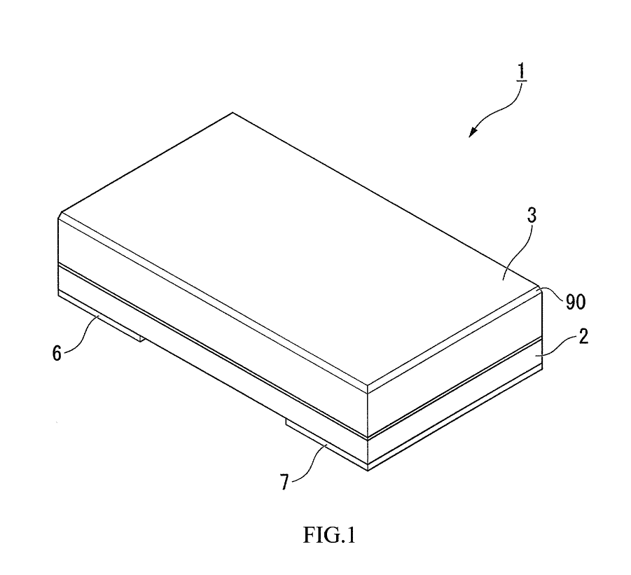

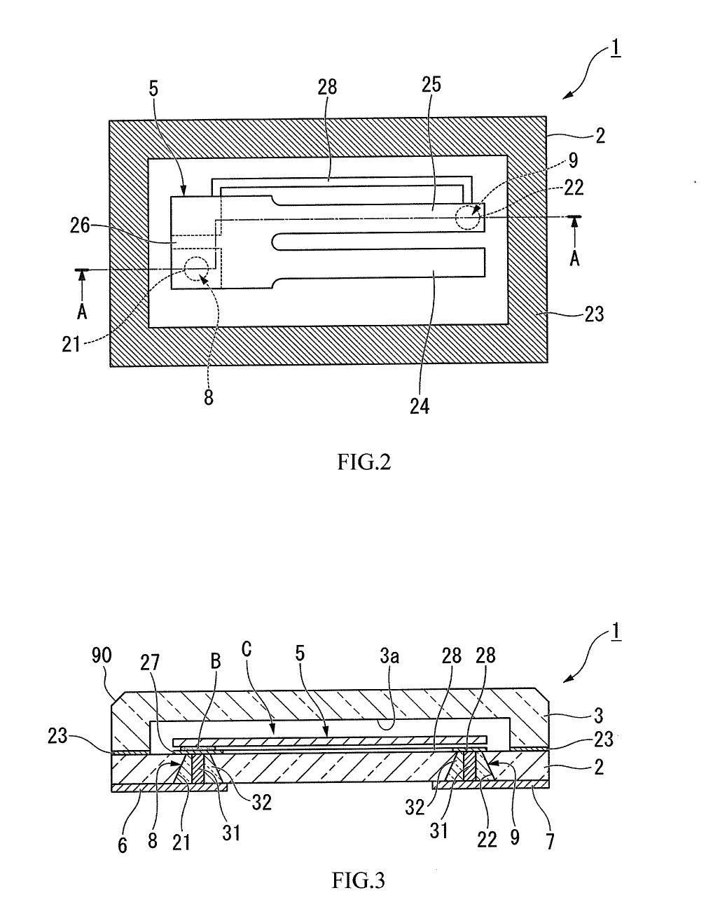

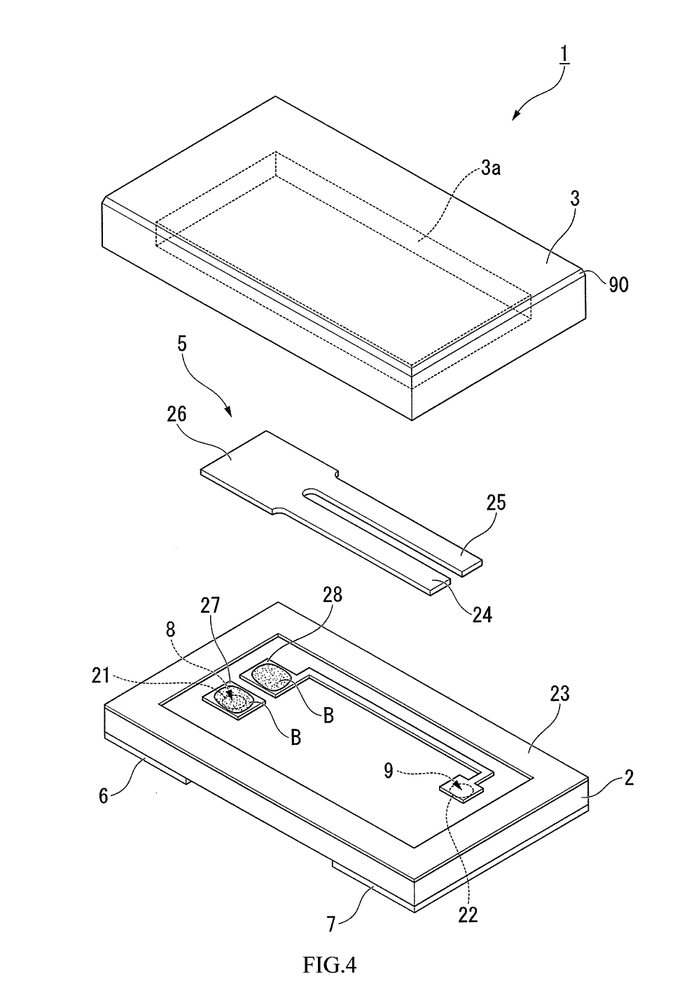

FIG. 1 is a perspective view showing an external appearance of a piezoelectric vibrator according to an embodiment. FIG. 2 is a plan view showing an inner structure of the piezoelectric vibrator when a piezoelectric vibrating reed is viewed from above with the lid substrate removed. FIG. 3 is a cross-sectional view of the piezoelectric vibrator taken along the line A-A in FIG. 2, and FIG. 4 is an exploded perspective view of the piezoelectric vibrator.

As shown in FIGS. 1 to 4, a piezoelectric vibrator 1 is a surface mounted device-type piezoelectric vibrator 1 which is formed in the form of a box laminated in two layers of a base substrate 2 and a lid substrate 3 and in which a piezoelectric vibrating reed 5 is accommodated in a cavity C at an inner portion thereof. The piezoelectric vibrating reed 5 and external electrodes 6 and 7 which are provided at an outer side of the base substrate 2 are electrically connected to each other by a pair of penetration electrodes 8 and 9 penetrating through the base substrate 2.

The base substrate 2 is a transparent insulating substrate made of a glass material, for example, soda-lime glass, and is formed in a plate-like shape. The base substrate 2 is formed with a pair of through holes 21 and 22 in which a pair of penetration electrodes 8 and 9 is formed. The through holes 21 and 22 are formed in a tapered form in cross-sectional view whose diameter gradually decreases from the outer end surface (the lower surface in FIG. 3) of the base substrate 2 toward the inner end surface (the upper surface in FIG. 3).

The lid substrate 3 is a transparent insulating substrate made of glass material, for example, soda-lime glass, similarly to the base substrate 2, and is formed in a plate-like shape having a size capable of being superimposed on the base substrate 2. A bonding surface side of the lid substrate 3 to be bonded to the base substrate 2 is formed with a rectangular recess 3a in which the piezoelectric vibrating reed 5 is accommodated.

The recess 3a forms the cavity C that accommodates the piezoelectric vibrating reed 5 when the base substrate 2 and the lid substrate 3 are superimposed on each other. The lid substrate 3 is anodically bonded to the base substrate 2 with a bonding layer (bonding material) 23 described later disposed therebetween in a state where the recess 3a faces the base substrate 2. On the upper peripheral edge of the lid substrate 3, chamfered portions 90 are formed by chamfering the corners of the lid substrate 3 during a scribing step, described later, of the process of manufacturing the piezoelectric vibrator 1.

The piezoelectric vibrating reed 5 is a tuning-fork type vibrating reed which is made of a piezoelectric material such as crystal, lithium tantalate, or lithium niobate and is configured to vibrate when a predetermined voltage is applied thereto.

The piezoelectric vibrating reed 5 is a square bracket shape in the plan view which includes a pair of vibrating arms 24 and 25 disposed in parallel to each other and a base portion 26 to which the base end sides of the pair of vibrating arms 24 and 25 are integrally fixed. The piezoelectric vibrating reed 5 includes an excitation electrode which is formed on the outer surfaces of the pair of vibrating arms 24 and 25 so as to allow the pair of vibrating arms 24 and 25 to vibrate and includes a pair of first and second excitation electrodes (not shown); and a pair of mount electrodes (not shown) which electrically connects the first and second excitation electrodes.

As shown in FIGS. 3 and 4, the piezoelectric vibrating reed 5 configured in this way is bump-bonded on lead-out electrodes 27 and 28, which are formed on the inner end surface of the base substrate 2, using bumps B made of gold or the like. More specifically, the first excitation electrode of the piezoelectric vibrating reed 5 is bump-bonded on one lead-out electrode 27 via one mount electrode and the bumps B, and the second excitation electrode is bump-bonded on the other lead-out electrode 28 via the other mount electrode and the bumps B. In this way, the piezoelectric vibrating reed 5 is supported in a state of being floated from the inner end surface of the base substrate 2, and the mount electrodes and the lead-out electrodes 27 and 28 are electrically connected to each other.

A bonding layer 23 for anodic bonding made of a conductive material (for example, aluminum) is formed on the inner end surface side of the base substrate 2 (the bonding surface side to be bonded to the lid substrate 3). The bonding layer 23 is formed along the peripheral edge of the base substrate 2 so as to surround the periphery of the recess 3a formed on the lid substrate 3. The base substrate 2 and the lid substrate 3 are anodically bonded with the bonding layer 23 disposed therebetween in a state where the recess 3a faces the bonding surface of the base substrate 2.

The external electrodes 6 and 7 are provided at both ends in the longitudinal direction of the outer end surface of the base substrate 2 and are electrically connected to the piezoelectric vibrating reed 5 via the penetration electrodes 8 and 9 and the lead-out electrodes 27 and 28. More specifically, one external electrode 6 is electrically connected to one mount electrode of the piezoelectric vibrating reed 5 via one penetration electrode 8 and one lead-out electrode 27. On the other hand, the other external electrode 7 is electrically connected to the other mount electrode of the piezoelectric vibrating reed 5 via the other penetration electrode 9 and the other lead-out electrode 28.

The penetration electrodes 8 and 9 are formed by a cylindrical member 32 and a core portion 31 which are integrally fixed to the through holes 21 and 22 by baking. The penetration electrodes 21 and 22 serve to maintain airtightness in the cavity C by completely closing the through holes 21 and 22 and achieve electrical connection between the external electrodes 6 and 7 and the lead-out electrodes 27 and 28. Specifically, one penetration electrode 8 is disposed below the lead-out electrode 27 and between the external electrode 6 and the base portion 26. The other penetration electrode 9 is disposed above the external electrode 7 and below the lead-out electrode 28.

The cylindrical member 32 is obtained by baking a paste-like glass frit. The cylindrical member 32 has a cylindrical shape in which both ends are flat and which has approximately the same thickness as the base substrate 2. The core portion 31 is disposed at the center of the cylindrical member 32 so as to penetrate through a central hole 32c of the cylindrical member 32. In the present embodiment, the cylindrical member 32 has an approximately conical outer shape (a tapered cross-sectional shape) so as to match the shapes of the through holes 21 and 22. The cylindrical member 32 is baked in a state of being embedded in the through holes 21 and 22 and is tightly attached to the through holes 21 and 22.

The core portion 31 is a conductive cylindrical core material made of metallic material, and similarly to the cylindrical member 32, has a shape of which both ends are flat and which has approximately the same thickness as the base substrate 2.

The electrical connection of the penetration electrodes 8 and 9 is secured by the conductive core portion 31.

When the piezoelectric vibrator 1 configured in this manner is operated, a predetermined driving voltage is applied between the pair of external electrodes 6 and 7 formed on the base substrate 2. In this way, a current can be made to flow to the excitation electrodes of the piezoelectric vibrating reed 5, and the pair of vibrating arms 24 and 25 is allowed to vibrate at a predetermined frequency in a direction moving closer to or away from each other. This vibration of the pair of vibrating arms 24 and 25 can be used as the time source, the timing source of a control signal, the reference signal source, and the like.

### (Piezoelectric Vibrator Manufacturing Method)

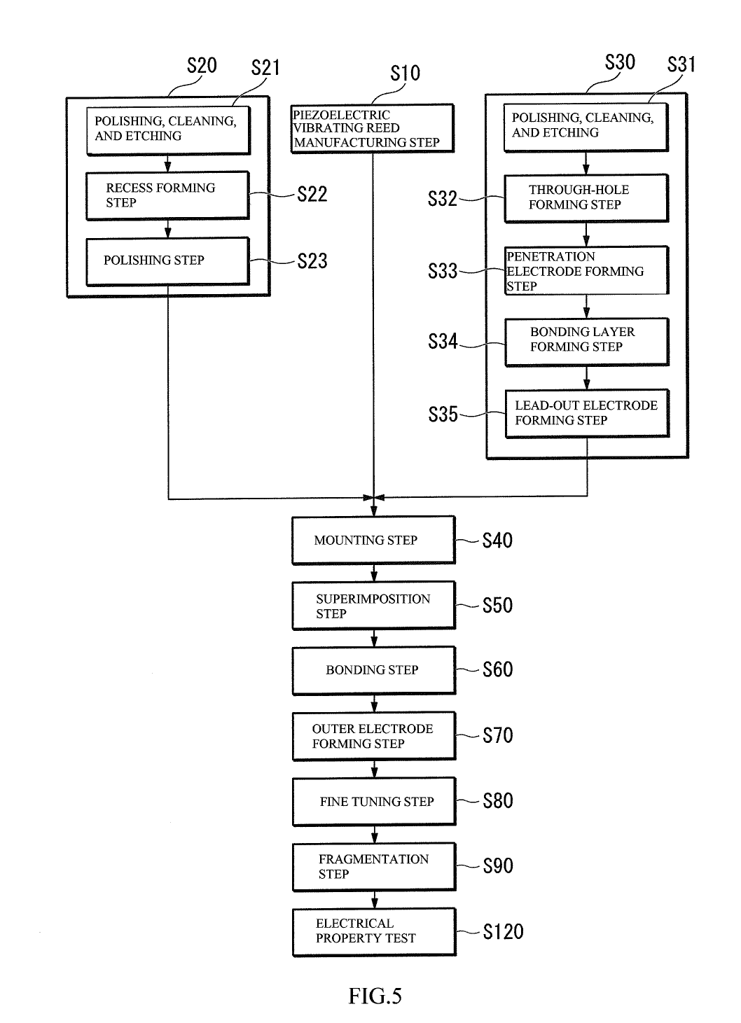

Next, a method of manufacturing the above-described piezoelectric vibrator will be described with reference to the flowchart shown in FIG. 5.

First, as shown in FIG. 5, a piezoelectric vibrating reed manufacturing step is performed to manufacture the piezoelectric vibrating reed 5 shown in FIGS. 1 to 4 (S10). Moreover, after the piezoelectric vibrating reed 5 is manufactured, rough tuning of a resonance frequency is performed. Fine tuning of adjusting the resonance frequency more accurately is performed when a mounting step is performed.

### (First Wafer Manufacturing Step)

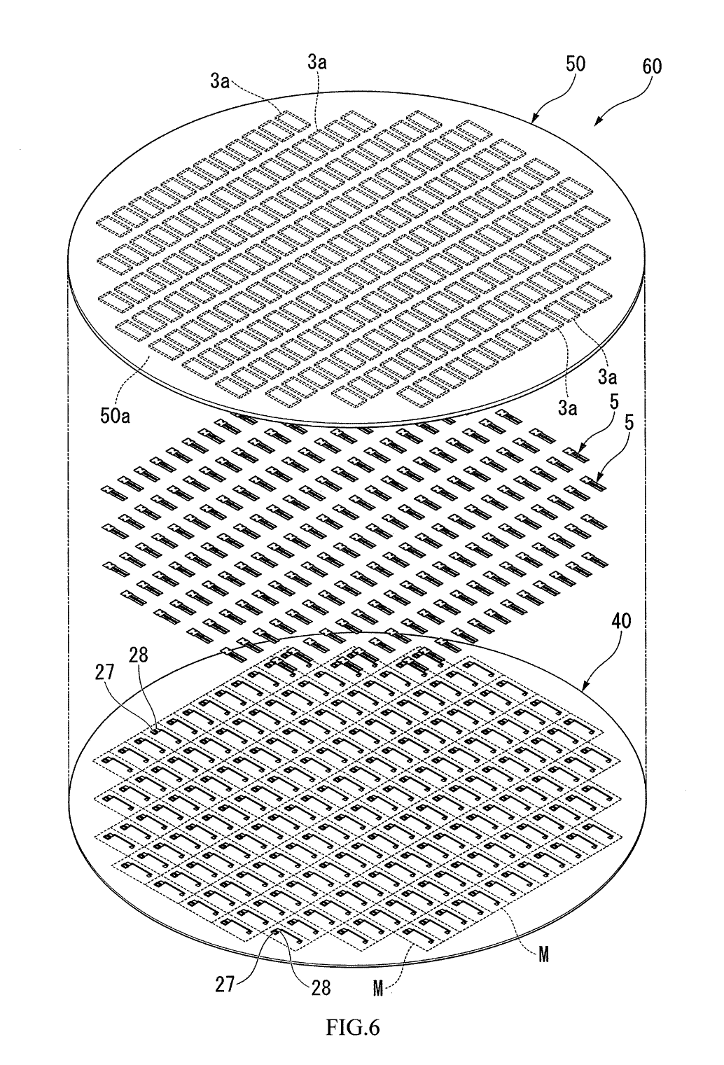

FIG. 6 is an exploded perspective view of a wafer assembly in which a base substrate wafer and a lid substrate wafer are anodically bonded to each other with the piezoelectric vibrating reed accommodated in the cavity.

Subsequently, as shown in FIGS. 5 and 6, a first wafer manufacturing step is performed where a lid substrate wafer 50 later serving as the lid substrate 3 is manufactured up to the stage immediately before anodic bonding is performed (S20). Specifically, a disk-shaped lid substrate wafer 50 is formed by polishing a soda-lime glass to a predetermined thickness, cleaning the polished glass, and removing the affected uppermost layer by etching or the like (S21). After that, a recess forming step is performed where a plurality of recesses 3a to be used as cavities C is formed in a matrix form on an inner end surface 50a (the lower surface in FIG. 6) of the lid substrate wafer 50 by etching or the like (S22).

Subsequently, in order to secure airtightness between the lid substrate wafer 50 and a base substrate wafer 40 described later, a polishing step (S23) is performed where at least the inner end surface 50a of the lid substrate wafer 50 serving as the bonding surface to be bonded to the base substrate wafer 40 is polished so that the inner end surface 50a has a mirror-like surface. In this way, the first wafer manufacturing step (S20) ends.

### (Second Wafer Manufacturing Step)

Subsequently, at the same or a different time as the first wafer manufacturing step, a second wafer manufacturing step is performed where a base substrate wafer 40 later serving as the base substrate 2 is manufactured up to the stage immediately before anodic bonding is performed (S30). In this step, first, a disk-shaped base substrate wafer 40 is formed by polishing a soda-lime glass to a predetermined thickness, cleaning the polished glass, and removing the affected uppermost layer by etching or the like (S31). After that, a through hole forming step is performed where a plurality of through holes 21 and 22 for disposing a pair of penetration electrodes 8 and 9 on the base substrate wafer 40 is formed by press working or the like (S32). Specifically, the through holes 21 and 22 can be formed by forming recesses on one surface of the base substrate wafer 40 by press working or the like and then polishing the other surface of the base substrate wafer 40 so as to penetrate through the recesses.

Subsequently, a penetration electrode forming step (S33) is performed where penetration electrodes 8 and 9 are formed in the through holes 21 and 22 formed during the through hole forming step (S32). By doing so, in the through holes 21 and 22, and the core portions 31 are maintained to be flush with both end surfaces 40a and 40b (the upper and lower surfaces in FIG. 6) of the base substrate wafer 40. In this way, the penetration electrodes 8 and 9 can be formed.

Subsequently, a bonding layer forming step is performed where a conductive material is patterned on the inner end surface 40a of the base substrate wafer 40 so as to form a bonding layer 23 (S34), and a lead-out electrode forming step is performed (S35). The bonding layer 23 is formed on a region of the base substrate wafer 40 other than the formation region of the cavity C, namely the entire bonding region of the base substrate wafer 40 to be bonded to the inner end surface 50a of the lid substrate wafer 50. In this way, the second wafer manufacturing step (S30) ends.

Subsequently, the piezoelectric vibrating reed 5 manufactured by the piezoelectric vibrating reed manufacturing step (S10) is mounted on the lead-out electrodes 27 and 28 of the base substrate wafer 40 manufactured by the second wafer manufacturing step (S30) with bumps B made of gold or the like disposed therebetween (S40). Then, a superimposition step is performed where the base substrate wafer 40 and the lid substrate wafer 50 manufactured by the first and second wafer manufacturing steps are superimposed on each other (S50). Specifically, the two wafers 40 and 50 are aligned at a correct position using reference marks or the like not shown in the figure as indices. In this way, the mounted piezoelectric vibrating reed 5 is accommodated in the cavity C surrounded by the recess 3a formed on the lid substrate wafer 50 and the base substrate wafer 40.

After the superimposition step is performed, a bonding step is performed where anodic bonding is performed under a predetermined temperature atmosphere with application of a predetermined voltage in a state where the two superimposed wafers 40 and 50 are inserted into an anodic bonding machine not shown and the outer peripheral portions of the wafers are clamped by a holding mechanism not shown (S60). Specifically, a predetermined voltage is applied between the bonding layer 23 and the lid substrate wafer 50. Then, an electrochemical reaction occurs at the interface between the bonding layer 23 and the lid substrate wafer 50, whereby they are strengthened and tightly adhered and anodically bonded. In this way, the piezoelectric vibrating reed 5 can be sealed in the cavity C, and a wafer assembly 60 can be obtained in which the base substrate wafer 40 and the lid substrate wafer 50 are bonded to each other. According to the present embodiment, by anodically bonding the two wafers 40 and 50, as compared to the case of bonding the two wafers 40 and 50 by an adhesive or the like, it is possible to prevent positional shift due to aging or impact and warping or the like of the wafer assembly 60 and bond the two wafers 40 and 50 more tightly.

After that, a pair of external electrodes 6 and 7 is formed so as to be electrically connected to the pair of penetration electrodes 8 and 9 (S70), and the frequency of the piezoelectric vibrator 1 is finely tuned (S80).

### (Fragmentation Step)

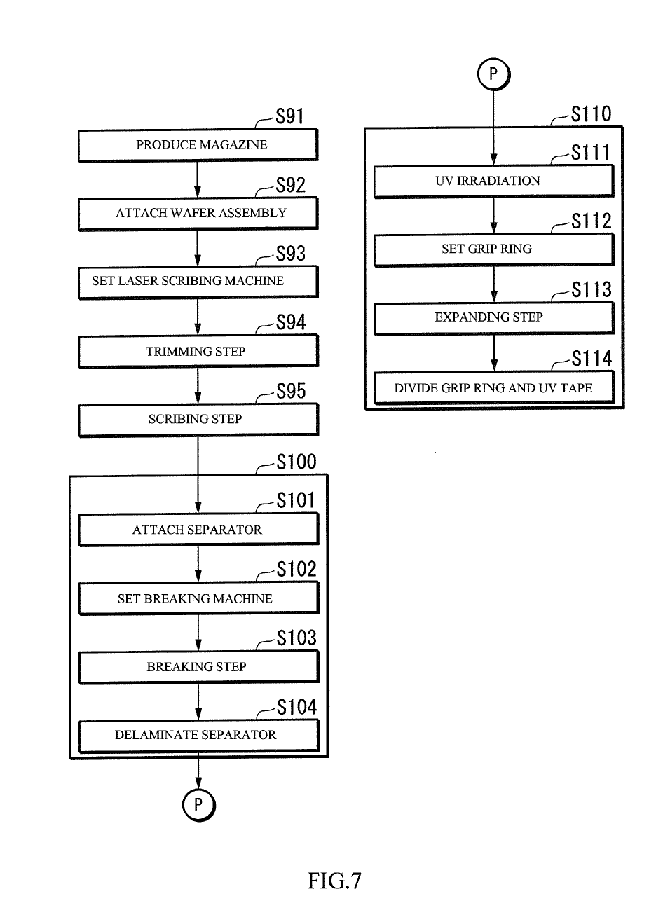

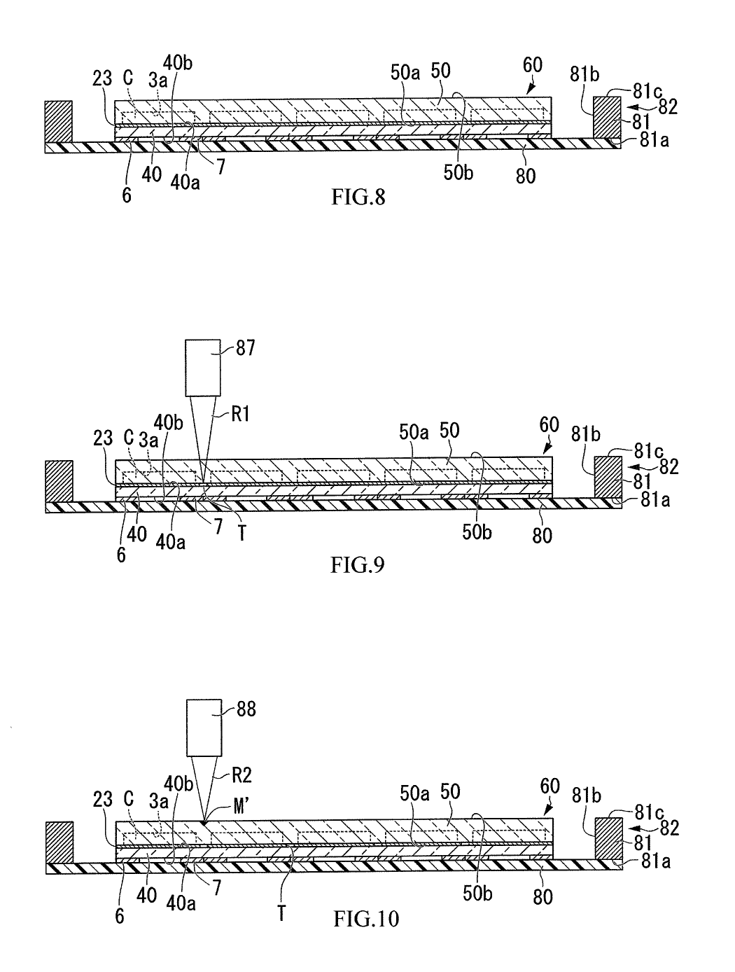

FIG. 7 is a flowchart showing the flow of a fragmentation step of the wafer assembly. FIGS. 8 to 13 are cross-sectional views of the wafer assembly illustrating the fragmentation step.

After the fine tuning of the frequency is completed, a fragmentation step is performed where the bonded wafer assembly 60 is cut into small fragments (S90).

In the fragmentation step (S90), as shown in FIGS. 7 and 8, a magazine 82 for holding the wafer assembly 60 is produced using a UV tape 80 and a ring frame 81 (S91). The ring frame 81 is a ring-shaped member whose inner diameter is larger than the diameter of the wafer assembly 60 and has the same thickness as the wafer assembly 60. The UV tape 80 is a polyolefin sheet coated with an acrylic adhesive, and specifically, UHP-1525M3 available from Denki Kagaku Kogyo K.K., D510T available from Lynntech Inc., and the like are suitably used. The thickness of the sheet material of the UV tape is preferably about 170 μm. If a UV tape whose sheet material is thinner than 170 μm is used, there is a possibility that the UV tape 80 may be cut together with the wafer assembly 60 in a breaking step (S103) described later, it is therefore not desirable.

The magazine 82 can be produced by attaching the UV tape 80 on one surface 81a of the ring frame 81 so as to close a penetration hole 81b. Moreover, the wafer assembly 60 is attached to an adhesion surface of the UV tape 80 in a state where the central axis of the ring frame 81 is identical to the central axis of the wafer assembly 60 (S92). Specifically, an outer end surface 40b side (an external electrode side) of the base substrate wafer 40 is attached to the adhesion surface of the UV tape 80. In this way, the wafer assembly 60 is set within the penetration hole 81b of the ring frame 81. In this state, the wafer assembly 60 is transferred to a laser scribing machine (not shown) (S93).

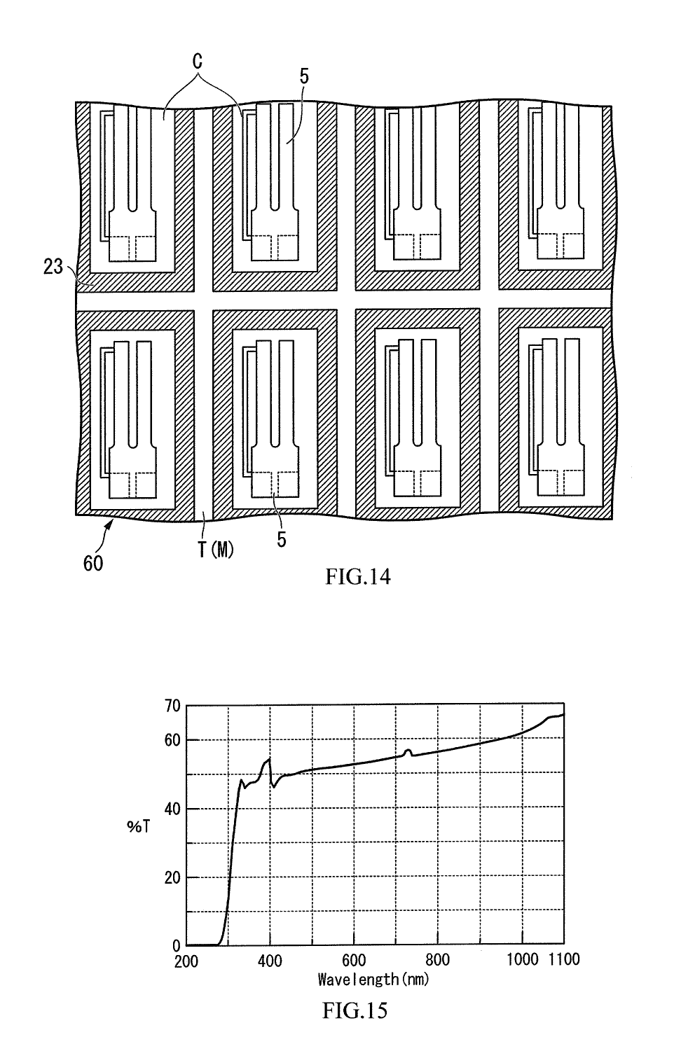

FIG. 14 is a plan view illustrating a trimming step, showing the base substrate wafer of the wafer assembly with the lid substrate wafer removed.

As shown in FIGS. 9 and 14, a trimming step (first laser irradiation step) is performed where the bonding layer 23 bonding the lid substrate wafer 50 and the base substrate wafer 40 together is delaminated (S94). In the trimming step (S94), the bonding layer 23 in the irradiation region of a laser beam R1 is melted using a laser that emits a beam having the absorption wavelength of the bonding layer 23, for example, a first laser 87 configured by a second-harmonic laser having a wavelength of 532 nm. In this case, the laser beam R1 emitted from the first laser 87 is reflected by a beam scanner (galvanometer) and is then focused through an Fθ lens. The first laser 87 is moved in parallel and relative to the wafer assembly 60 while irradiating the focused laser beam R1 from a side of the wafer assembly 60 close to the outer end surface 50b of the lid substrate wafer 50. Specifically, the first laser 87 is scanned on the partition walls that divide the cavities C, namely along the outline (intended cutting line) M (see FIG. 6) of the piezoelectric vibrator 1.

The spot diameter of the laser beam R1 in the trimming step (S94) is preferably set to 10 μm or more and 30 μm or less, for example, and in the present embodiment, is set to about 20 μm. As the other conditions of the trimming step (S94), it is preferable that the average output at the processing point of the first laser 87 is set to 1.0 W, and a frequency modulation amplitude and a scanning speed are set to about 20 kHz and 200 mm/sec, respectively, for example.

In this way, the bonding layer 23 on the outline M is heated by absorbing the laser beam R1, whereby the bonding layer 23 is melted and contracted toward the outer side from the irradiation region (outline M) of the laser beam R1. As a result, a trimming line T where the bonding layer 23 is delaminated from the bonding surface is formed on the bonding surfaces of the two wafers 40 and 50 (the inner end surface 50a of the lid substrate wafer 50 and the inner end surface 40a of the base substrate wafer 40).

Subsequently, as shown in FIG. 10, a surface layer portion of the outer end surface 50b of the lid substrate wafer 50 is irradiated with a laser beam R2 to form a scribe line M′ on the wafer assembly 60 (S95: scribing step (second laser irradiation step)). In the scribing step (S95), the surface layer portion of the lid substrate wafer 50 in the laser irradiation region is melted using a laser that emits a beam having the absorption wavelength of the lid substrate wafer 50 (soda-lime glass), for example, a second laser 88 configured by a UV-Deep laser having a wavelength of 266 nm. Specifically, similar to the trimming step (S94), the second laser 88 is moved in parallel and relative to the wafer assembly 60, and the second laser 88 is scanned along the outline M of the piezoelectric vibrator 1. By doing so, the surface layer portion of the lid substrate wafer 50 is heated by absorbing the laser beam R2, whereby the lid substrate wafer 50 is melted and the scribe line M′ having a V-groove form is formed. As described above, the first laser 87 and the second laser 88 are scanned along the outline M of each piezoelectric vibrator 1. In this way, the trimming line T where the bonding layer 23 is delaminated and the scribe line M′ are arranged so that they overlap with each other as viewed from the thickness direction of the wafer assembly 60.

In the scribing step (S95), the spot diameter of the laser beam R2 in the surface layer portion of the lid substrate wafer 50 is preferably set, for example, to about 10 μm or more and 30 μm or less. In the present embodiment, the spot diameter is set to about 20 μm. This is set considering the width (the cutting zone of the wafer assembly 60) and the depth of the scribe line M′. If the spot diameter is less than 10 μm, it is difficult to form the scribe line M′ to a desired depth. On the other hand, if the spot diameter is more than 30 μm, since the width of the scribe line M′ is too large, and the cutting zone of the wafer assembly 60 becomes large, it is not desirable. As other conditions of the scribing step (S95), it is preferable that an output at the processing point of the second laser 88 is set to 250 mW to 600 mW, and pulse energy to 100 processing threshold fluence to 30 J/(cm²·pulse), and scanning speed to about 40 mm/sec to 60 mm/sec, for example.

Subsequently, a cutting step is performed where the wafer assembly 60 on which the scribe line M′ is formed is cut into individual piezoelectric vibrators 1 (S100).

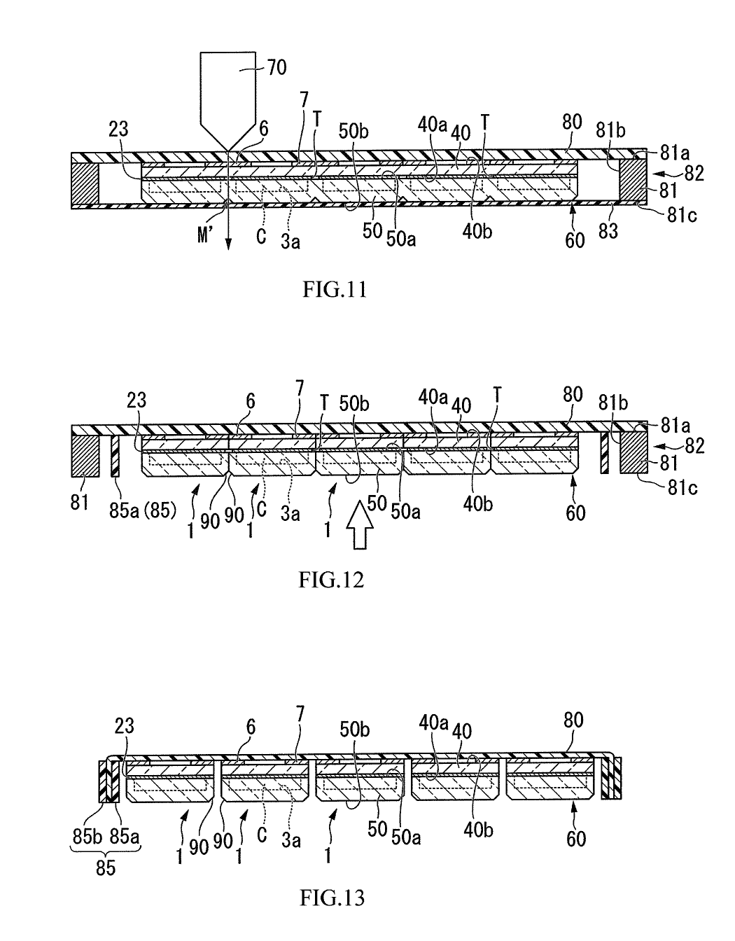

In the cutting step (S100), first, as shown in FIG. 11, a separator 83 is attached to another surface 81c of the ring frame 81 so as to close the penetration hole 81b (S101). As a material of the separator 83, a polyethylene terephthalate film (a so-called PET film), for example, LUMIRROR T60 (product of TORAY) (20 μm to 60 μmt), is ideally used. In this way, the wafer assembly 60 is held within the penetration hole 81b of the ring frame 81 in a state of being sandwiched between the UV tape 80 and the separator 83. In this state, the wafer assembly 60 is transferred to a breaking machine (S102).

Subsequently, a breaking step is performed where a breaking stress is applied to the wafer assembly 60 transferred to the breaking machine (S103). In the breaking step (S103), a cutting blade 70 (whose blade edge angle is 60° to 90°, for example) whose blade length is larger than the diameter of the wafer assembly 60 is prepared. Then, the cutting blade 70 is positioned on the scribe line M′ (the trimming line T) from the side of the outer end surface 40b of the base substrate wafer 40 and is brought into press contact with the base substrate wafer 40. In this way, a crack is formed along the thickness direction of the wafer assembly 60, and the wafer assembly 60 is cut in such a way that it is divided along the scribe line M′ formed on the lid substrate wafer 50. By pressing the cutting blade 70 on each scribe line M′, it is possible to divide the wafer assembly 60 into packages for each outline M at once. After that, the separator 83 attached to the wafer assembly 60 is detached (S104). According to the present embodiment, in the breaking step (S103), by applying the breaking stress along the scribe line M′ from the side opposite to the formation region of the scribe line M′, namely the outer end surface 40b of the base substrate wafer 40, it is possible to cut the wafer assembly 60 in a smoother and easier manner. Therefore, a cutting surface having even better surface precision can be obtained. In addition, the breaking stress is a tensional stress that is generated in the direction away from the scribe line M (the direction where the piezoelectric vibrators 1 are separated from each other).

Subsequently, a pickup step for picking up the fragmented piezoelectric vibrators 1 is performed (S110). In the pickup step (S110), first, a UV beam is irradiated onto the UV tape 80 of the magazine 82 to decrease the adhesive force of the UV tape 80 (S111). Subsequently, as shown in FIG. 12, an inner ring 85a of a grip ring 85 is set in the penetration hole 81b of the ring frame 81 so as to surround the perimeter of the wafer assembly 60 (S112). The grip ring 85 is a ring made of resin whose inner diameter is larger than the outer diameter of the wafer assembly 60 and smaller than the inner diameter of the penetration hole 81b of the ring frame 81. The grip ring 85 is configured by the inner ring 85a and an outer ring 85b (see FIG. 13) whose inner diameter is the same as the outer diameter of the inner ring 85a. That is, the inner ring 85a is stuck to the inner side of the outer ring 85b.

Subsequently, in order to make it easy to pick out the fragmented piezoelectric vibrators 1, an expanding step is performed so as to expand the space between the piezoelectric vibrators 1 (S113). Specifically, the inner ring 85a is pushed toward the side of the UV tape 80 for each wafer assembly 60 (see the arrow in FIG. 12). By doing so, the UV tape 80 is expanded toward the outer side in the diameter direction of the wafer assembly 60, whereby the piezoelectric vibrators 1 attached to the UV tape 80 are separated from each other, and the space between the adjacent piezoelectric vibrators 1 increases. Moreover, as shown in FIG. 13, in this state, the outer ring 85b is set at the outer side of the inner ring 85a. Specifically, the inner ring 85a and the outer ring 85b are fitted to each other with the UV tape 80 interposed therebetween. In this way, the UV tape 80 in the expanded state is held on the grip ring 85. Moreover, the UV tape 80 at the outer side of the grip ring 85 is cut, and the ring frame 81 and the grip ring 85 are divided.

After that, a UV beam is irradiated onto the UV tape 80 again so as to further decrease the adhesive force of the UV tape 80. In this way, the piezoelectric vibrators 1 are separated from the UV tape 80. Thereafter, the piezoelectric vibrators 1 separated from the UV tape 80 are picked out one by one. In the present embodiment, in order to achieve fragmentation along the scribe line M′ of the lid substrate wafer 50 during the breaking step (S103), chamfered portions 90 in which C-chamfering (for example, about C10 μm) is achieved by the scribe line M′ are formed on the upper peripheral edge of the lid substrate 3 of the fragmented piezoelectric vibrator 1.

In this way, a plurality of two-layered surface mounted device-type piezoelectric vibrators 1 shown in FIG. 1, in which the piezoelectric vibrating reed 5 is sealed in the cavity C formed between the base substrate 2 and the lid substrate 3 being anodically bonded together, can be manufactured at a time.

Subsequently, as shown in FIG. 5, an internal electrical property test is conducted (S120). That is, the resonance frequency, resonance resistance value, drive level properties (the excitation power dependence of the resonance frequency and the resonance resistance value), and the like of the piezoelectric vibrating reed 5 are measured and checked. Moreover, the insulation resistance properties and the like are checked as well. Finally, an external appearance test of the piezoelectric vibrator 1 is conducted to check the dimensions, the quality, and the like. In this way, the manufacturing of the piezoelectric vibrator 1 ends.

As described above, in the present embodiment, during the fragmentation step (S90) of the piezoelectric vibrator 1, after performing the trimming step (S94) of delaminating the bonding layer 23 on the outline M from the two wafers 40 and 50, and the wafer assembly 60 is broken using the cutting blade 70 through the scribing step (S95).

According to this configuration, by forming the scribe line M′ on the surface layer portion of the lid substrate wafer 50 along the outline M prior to the breaking step (S103), it is possible to provide merits such as, for example, a very small cutting zone, a high cutting speed, good surface precision of the cutting surface, and less chipping, as compared to the blade cutting method of the related art. Moreover, since there is no possibility of forming a damaged layer inside the wafer assembly 60, no crack will be formed in the surface direction of the wafer assembly 60 when cutting the wafer assembly 60, and the mechanical durability of the piezoelectric vibrator 1 after the cutting will not decrease.

In particular, by delaminating the bonding layer 23 on the outline M before the scribing step (S95), it is possible to facilitate the progress of cracking in the thickness direction of the wafer assembly 60 during breaking and to prevent the progress of cracking in the surface direction of the wafer assembly 60. Therefore, the wafer assembly 60 is cut along the outline M in a smooth and easy manner. As a result, it is possible to improve surface precision of the cutting surface and to prevent breaking or the like of the wafer assembly 60 during breaking, thus cutting the wafer assembly 60 to a desired size. In this way, it is possible to secure airtightness in the cavity C and provide the piezoelectric vibrator 1 having excellent vibration properties and high reliability.

Therefore, it is possible to increase the number of piezoelectric vibrators 1 picked out as non-defective products from one wafer assembly 60 and thus to improve yield.

In addition, the lid substrate 3 of the piezoelectric vibrator 1 according to the present embodiment is formed with the chamfered portions 90 on the peripheral portion thereof.

According to this configuration, even when a mechanism for picking out the piezoelectric vibrator 1 comes into contact with the corners of the piezoelectric vibrator 1 during the pickup step (S110) when the fragmented piezoelectric vibrators 1 are picked out, since it is possible to suppress generation of chipping associated with contacting, the piezoelectric vibrators 1 can be picked out easily.

Moreover, the chamfered portions 90 can be formed automatically by cutting along the scribe line M′ after forming the scribe line M′ with laser irradiation of the second laser 88. Therefore, it is possible to form the chamfered portions 90 more quickly and easily as compared to the case of forming the chamfered portions 90 in the respective cut piezoelectric vibrators 1. As a result, it is possible to improve workability.

Furthermore, by cutting the wafer assembly 60 along the scribe line M′, it is possible to improve the cutting precision of the cutting surface of the piezoelectric vibrator 1 and provide the piezoelectric vibrator 1 having high reliability.

### (First Laser Selection Test)

Here, the present inventor has conducted a first laser selection test in order to select the first laser ideal for the trimming step. FIG. 15 is a graph showing the relationship between wavelength (nm) and transmittance (%).

First, in the trimming step of the present embodiment, as described above, it is necessary to use a laser which passes through the lid substrate wafer 50 and reaches the bonding layer 23 in order to delaminate the bonding layer 23 from the two wafers 40 and 50 (see FIG. 9). Therefore, in this test, as shown in FIG. 15, the bonding layer 23 was delaminated using a YAG (Yttrium Aluminum Garnet) laser having a wavelength of 1030 nm and a second-harmonic laser having a wavelength of 532 nm used in the present embodiment as a laser having transmittance of about 40% or more. Moreover, the trimming capabilities of the respective lasers, namely, the states of the bonding layer 23 in the laser irradiation region were measured.

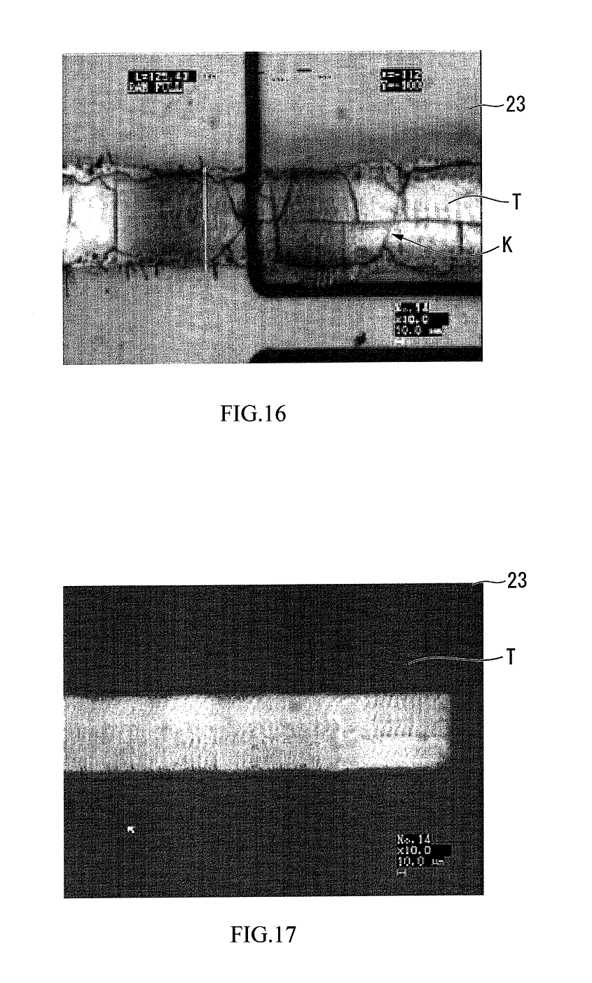

FIGS. 16 and 17 are views showing the state of the bonding layer 23 in the laser irradiation region in the first laser selection test, in which FIG. 16 shows the case of using the YAG laser, and FIG. 17 shows the case of using the second-harmonic laser used in the present embodiment.

As shown in FIG. 16, when trimming of the bonding layer 23 was performed using the YAG laser, a linear crack (so-called microcrack) (see reference numeral K in FIG. 16) was formed along the width direction of the trimming line T. When the breaking step was performed in the state where the microcrack was formed, it was difficult to cut the wafer assembly 60 along the desired outline M, and a lot of defective piezoelectric vibrators 1 were produced. The trimming width in FIG. 16 was set to 124 μm.

In contrast, as shown in FIG. 17, when the second-harmonic laser was used, the above-described microcrack was not formed in the trimming line T, and a good trimming state was obtained. It is considered to be attributable to the fact that when the second-harmonic laser emitting a beam of the absorption wavelength of the bonding layer 23 is used, since all the output of the laser beam is absorbed by the bonding layer 23 to heat the bonding layer 23, the bonding layer 23 is melted quickly, and the bonding layer 23 in the irradiation region of the laser beam is contracted toward the outer side from the irradiation region of the laser beam.

Given the above, by using the second-harmonic laser as the first laser 87 that performs the trimming step (S94), it is possible to form a desired trimming line T in which the bonding layer 23 on the outline M is completely delaminated. Therefore, in the subsequent breaking step (S103), it is possible to cut the wafer assembly 60 to a desired size.

### (Second Laser Selection Test)

Next, the present inventor has conducted a second laser selection test in order to select the second laser 88 used for the scribing step (S95). Specifically, the present inventor irradiated the surface layer of a glass substrate with a plurality of lasers having different wavelengths to form scribe lines on the surface layer of the glass substrate. Moreover, the quality of the formed scribe lines, the time consumed for forming the scribe lines, the cost, and the like were measured.

The present inventor conducted the second laser selection test using the lasers shown below.

### Example 1

UV-Deep Laser

Wavelength: 266 nm

### Comparative Example 1

ArF Excimer Laser

Wavelength: 193 nm

### Comparative Example 2

KrF Excimer Laser

Wavelength: 248 nm

### Comparative Example 3

UV-Deep Laser

Wavelength: 355 nm

### Comparative Example 4

Second-Harmonic Laser (Green Laser)

Wavelength: 532 nm

### Comparative Example 5

YAG Laser

Wavelength: 1030 nm or 1064 nm

### Comparative Example 6

CO₂ Laser

Wavelength: 10.6 μm

When scribe lines were formed using the above lasers, the results as shown in Table 1 were obtained. Table 1 shows the quality, speed, device cost, and overall evaluation based on these test results when scribe lines were formed using a plurality of lasers having different wavelengths.

TABLE 1

| | | | | Device | |
|---|---|---|---|---|---|
| | | Quality | Speed | Cost | Overall Evaluation Result |
| Comparative | ArF Excimer Laser | X | X | X | X: Significant chipping, much debris, not productive, |
| Example 1 | 193 nm | | | | large thermal absorption |
| Comparative | KrF Excimer Laser | X | X | X | X: Significant chipping, much debris, not productive, |
| Example 2 | 248 nm | | | | large thermal absorption |
| Example 1 | UV-Deep Laser | ⊚ | ◯ | ◯ | ⊚: Less chipping, less debris, good linearity |
| | 266 nm | | | | |
| Comparative | UV-Deep Laser | Δ | ◯ | ◯ | Δ: Significant chipping, less debris, meandering |
| Example 3 | 355 nm | | | | |
| Comparative | Green Laser | X | — | ◯ | X: Unable to process |
| Example 4 | 532 nm | | | | |
| Comparative | YAG Laser | X | — | ◯ | X: (1) Optimum for processing large plate into small |
| Example 5 | 1030 or 1064 nm | | | | pieces, unable to perform fragmentation |
| | | | | | (2) Limitation in device arrangement due to thermal stress |
| | | | | | (3) Unable to start cutting unless starting point is |
| | | | | | formed in advance during laser irradiation |
| Comparative | CO₂ Laser | Δ | ⊚ | ◯ | X: (1) Scribing image recognition is unstable, unable to |
| Example 6 | 10.6 μm | | | | perform fragmentation |
| | | | | | (2) Unable to start cutting unless starting point is |
| | | | | | formed in advance during laser irradiation |

As shown in Table 1, when scribe lines were formed using lasers (Comparative Examples 1 and 2) having shorter wavelengths than the UV-Deep laser used in the present embodiment, significant chipping and much debris (dust) were formed along the scribe lines. Furthermore, in the case of the lasers of Comparative Examples 1 and 2, it was unable to increase the laser output, the formation speed of scribe lines (laser scanning speed) was low, and the device cost was high.

Moreover, when the UV-Deep laser (Comparative Example 3) having a wavelength of 355 nm was used, significant chipping was formed, linearity was poor, and the scribe lines meandered.

Moreover, when the green laser, the YAG laser, and the CO₂ laser were used (Comparative Examples 4 to 6), as shown in FIG. 15, since their transmittance to the glass substrate is high, the laser is not absorbed in the glass substrate but passes therethrough. As a result, it was not possible to form desired scribe lines on the surface layer of the glass substrate.

Contrary to the comparative examples, when the UV-Deep laser having a wavelength of 266 nm was used in the scribing step as in Example 1, the laser beam was completely absorbed in the surface layer portion of the glass substrate, and it was possible to form desired scribe lines on the surface layer portion of the glass substrate. That is, since scribe lines having good linearity and less chipping and debris can be formed, it is possible to cut the wafer assembly 60 to a desired size in the subsequent breaking step (S103).

### (Oscillator)

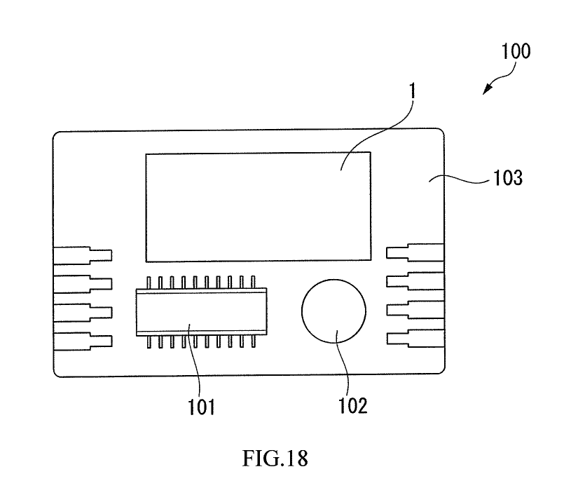

Next, an oscillator according to an embodiment of the invention will be described with reference to FIG. 18.

As shown in FIG. 18, an oscillator 100 of the present embodiment is one in which the piezoelectric vibrator 1 is configured as an oscillating piece that is electrically connected to an integrated circuit 101. The oscillator 100 includes a substrate 103 on which an electronic component 102 such as a capacitor is mounted. The integrated circuit 101 for the oscillator is mounted on the substrate 103, and the piezoelectric vibrator 1 is mounted in the vicinity of the integrated circuit 101. The electronic component 102, the integrated circuit 101, and the piezoelectric vibrator 1 are electrically connected by a wiring pattern which is not shown. It should be noted that these components are molded using resin which is not shown.

In the oscillator 100 configured in this manner, the piezoelectric vibrating reed 5 in the piezoelectric vibrator 1 vibrates when a voltage is applied to the piezoelectric vibrator 1. This vibration is converted to an electrical signal by the piezoelectric properties of the piezoelectric vibrating reed 5 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece.

By selectively setting the configuration of the integrated circuit 101, for example, as an RTC (Real Time Clock) module, according to the demand, it is possible to add a function of controlling the date or time for operating the device or an external device or providing the time or a calendar other than a single-function oscillator for a clock.

According to the oscillator 100 of the present embodiment, since the oscillator includes the piezoelectric vibrator 1 having improved quality, it is possible to achieve an improvement in the quality of the oscillator 100 itself. In addition to this, it is possible to obtain a highly accurate frequency signal which is stable over a long period of time.

### (Electronic Device)

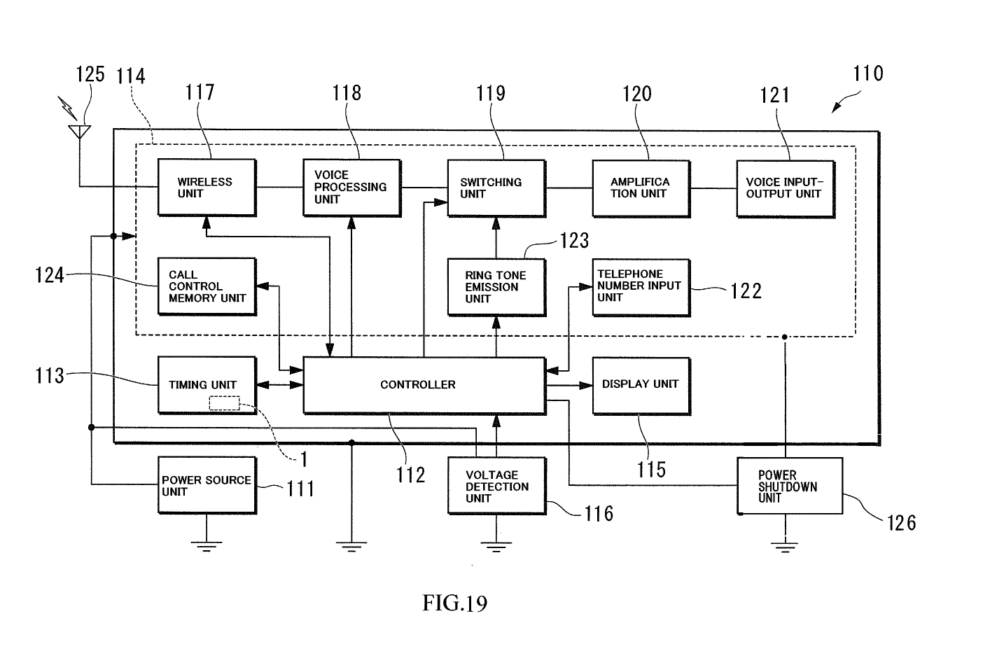

Next, an electronic device according to an embodiment of the invention will be described with reference to FIG. 19. The present embodiment will be described by way of an example of a mobile information device 110 having the piezoelectric vibrator 1 as an example of the electronic device. First, the mobile information device 110 of the present embodiment is represented, for example, by a mobile phone and is one that develops and improves on a wristwatch of the related art. The mobile information device 110 looks like a wristwatch in external appearance and is provided with a liquid crystal display at a portion corresponding to the dial pad and is capable of displaying the current time or the like on the screen. When the mobile information device 110 is used as a communication tool, the user removes it from the wrist and performs communication as with a mobile phone of the related art using the internal speaker and microphone on the inner side of its strap. However, the mobile information device 110 is remarkably small and light compared with the mobile phone of the related art.

Next, the configuration of the mobile information device 110 of the present embodiment will be described. As shown in FIG. 19, the mobile information device 110 includes the piezoelectric vibrator 1 and a power supply section 111 for supplying power. The power supply section 111 is formed, for example, of a secondary lithium battery. The power supply section 111 is connected in parallel to a control section 112 that performs various kinds of control, a clock section 113 that counts the time or the like, a communication section 114 that performs communication with the outside, a display section 115 that displays various kinds of information, and a voltage detection section 116 that detects voltages at the respective functional sections. The power supply section 111 supplies power to the respective functional sections.

The control section 112 controls the respective functional sections so as to control the operation of the overall system, such as operations to transmit and receive audio data and operations to count and display the current time. The control section 112 includes a ROM in which a program is written in advance, a CPU that reads out and runs the program written to the ROM, a RAM used as a work area of the CPU, and the like.

The clock section 113 includes an integrated circuit enclosing an oscillation circuit, a register circuit, a counter circuit, and an interface circuit, and the like as well as the piezoelectric vibrator 1. When a voltage is applied to the piezoelectric vibrator 1, the piezoelectric vibrating reed 5 vibrates, and this vibration is converted to an electrical signal by the piezoelectric properties of the quartz and is input to the oscillation circuit as the electrical signal. The output of the oscillation circuit is converted to a digital form and counted by the register circuit and the counter circuit. Signals are transmitted and received to and from the control section 112 via the interface circuit, and the current time and the current date, or the calendar information or the like are displayed on the display section 115.

The communication section 114 is provided with the same functions as those of the mobile phone of the related art, and includes a wireless section 117, an audio processing section 118, a switching section 119, an amplifier section 120, an audio input/output section 121, a telephone number input section 122, a ring tone generation section 123, and a call control memory section 124.

The wireless section 117 carries out transmission and reception of various kinds of data, such as audio data, with the base station via an antenna 125. The audio processing section 118 encodes and decodes an audio signal input therein from the wireless section 117 or the amplifier section 120. The amplifier section 120 amplifies a signal input therein from the audio processing section 118 or the audio input/output section 121 to a predetermined level. The audio input/output section 121 is formed of a speaker and a microphone and the like, and makes a ring tone and any incoming audio louder, as well as collecting sounds.

The ring tone generation section 123 generates a ring tone in response to a call from the base station. The switching section 119 switches the amplifier section 120 normally connected to the audio processing section 118 to the ring tone generation section 123 only when a call arrives, so that the ring tone generated in the ring tone generation section 123 is output to the audio input/output section 121 via the amplifier section 120.

The call control memory section 124 stores a program relating to incoming and outgoing call control for communication. The telephone number input section 122 includes, for example, numeric keys from 0 to 9 and other keys and the user inputs the telephone number of the communication party by depressing these numeric keys.

The voltage detection section 116 detects a voltage drop when a voltage being applied to each functional section, such as the control section 112, by the power supply section 111 drops below the predetermined value, and notifies the control section 112 of the detection of the voltage drop. The predetermined voltage value referred to herein is a value pre-set as the lowest voltage necessary to operate the communication section 114 in a stable manner, and for example, is about 3 V. Upon receipt of a notification of a voltage drop from the voltage detection section 116, the control section 112 disables the operation of the wireless section 117, the audio processing section 118, the switching section 119, and the ring tone generation section 123. In particular, it is essential to stop the operation of the wireless section 117 which consumes a large amount of power. Furthermore, a message informing the user that the communication section 114 is unavailable due to insufficient battery power is displayed on the display section 115.

More specifically, it is possible to disable the operation of the communication section 114 and display the notification message on the display section 115 by the voltage detection section 116 and the control section 112. This message may be displayed as a character message, or as a more intuitive indication, which may be displayed by putting a cross mark on the telephone icon displayed at the top of the display screen of the display section 115.

By providing a power shutdown section 126 capable of selectively shutting down the power to sections involved with the function of the communication section 114, it is possible to stop the function of the communication section 114 in a more reliable manner.

As described above, according to the mobile information device 110 of the present embodiment, since the mobile information device includes the piezoelectric vibrator 1 having improved quality, it is possible to achieve an improvement in the quality of the mobile information device itself. In addition to this, it is possible to display highly accurate clock information which is stable over a long period of time.

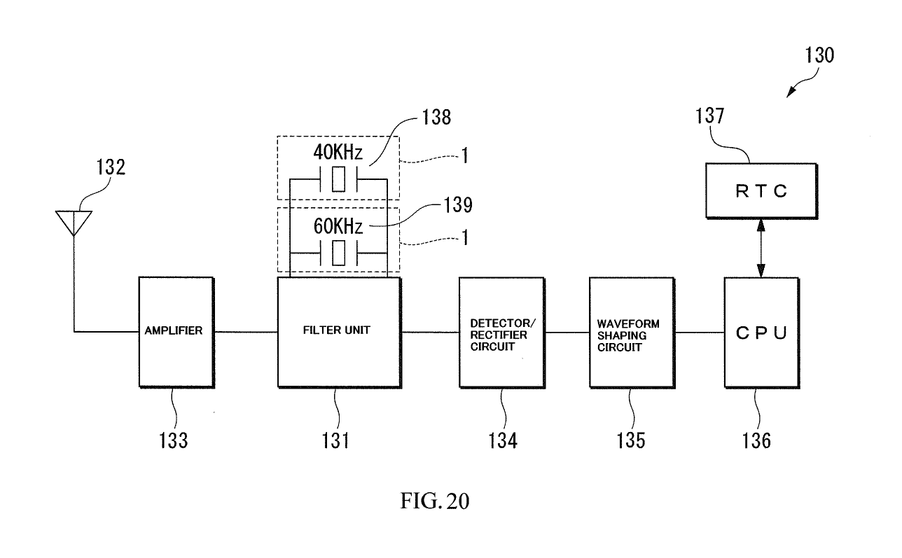

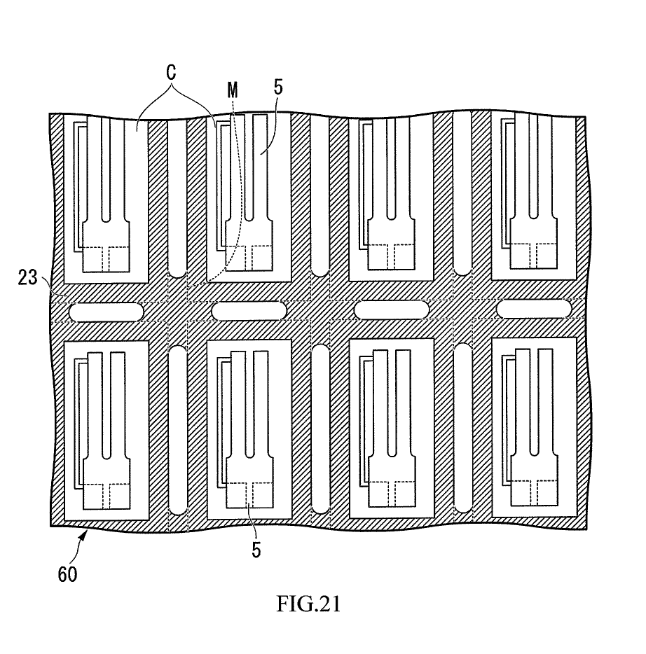

Next, a radio-controlled timepiece according to an embodiment of the invention will be described with reference to FIG. 20.

As shown in FIG. 20, a radio-controlled timepiece 130 of the present embodiment includes the piezoelectric vibrators 1 electrically connected to a filter section 131. The radio-controlled timepiece 130 is a clock provided with the function of displaying the correct time by automatically correcting the time upon receipt of standard radio waves which include the clock information.

In Japan, there are transmission centers (transmission stations) that transmit standard radio waves in Fukushima Prefecture (40 kHz) and Saga Prefecture (60 kHz), and each center transmits the standard radio waves. Waves as long as 40 kHz or 60 kHz have a nature to propagate along the land surface and a nature to propagate while reflecting between the ionosphere and the land surface, and therefore have a propagation range wide enough to cover all of Japan using the two transmission centers.

### (Radio-Controlled Timepiece)

Hereinafter, the functional configuration of the radio-controlled timepiece 130 will be described in detail.

An antenna 132 receives the long standard radio waves at 40 kHz or 60 kHz. The long standard radio waves are made up of time information called a time code which is modulated by the AM modulation scheme and carried on a carrier wave of 40 kHz or 60 kHz. The received long standard waves are amplified by an amplifier 133 and filtered and synchronized by the filter section 131 having a plurality of piezoelectric vibrators 1.

In the present embodiment, the piezoelectric vibrators 1 include quartz vibrator portions 138 and 139 having resonance frequencies of 40 kHz and 60 kHz which are the same as the carrier frequency.

Furthermore, the filtered signal at the predetermined frequency is detected and demodulated by a detection and rectification circuit 134.

Subsequently, the time code is extracted by a waveform shaping circuit 135 and counted by the CPU 136. The CPU 136 reads out information about the current year, the total number of days, the day of the week, and the time. The read information is reflected on the RTC 137 and the precise time information is displayed.

Because the carrier wave is 40 kHz or 60 kHz, a vibrator having the tuning-fork structure described above is suitable for the quartz vibrator portions 138 and 139.

Although the above description has been given of an example in Japan, the frequency of the long standard waves is different overseas. For example, standard waves of 77.5 kHz are used in Germany. When the radio-controlled timepiece 130 which is also operable overseas is incorporated into a portable device, a piezoelectric vibrator 1 set to a frequency different from the frequencies used in Japan is required.

According to the radio-controlled timepiece 130 of the present embodiment, since the radio-controlled timepiece includes the piezoelectric vibrator 1 having improved quality, it is possible to achieve an improvement in the quality of the radio-controlled timepiece itself. In addition to this, it is possible to count the time highly accurately and stably over a long period of time.

Although the embodiments of the invention have been described in detail with reference to the drawings, the detailed configuration is not limited to the embodiments, and various changes can be made in design without departing from the spirit of the invention.

In addition, although the embodiment has been described by way of an example of a tuning-fork type piezoelectric vibrating reed 5, the piezoelectric vibrating reed of the invention is not limited to the tuning-fork type piezoelectric vibrating reed. For example, the piezoelectric vibrating reed may be a thickness-shear type vibrating reed.

In addition, although the embodiment has been described for the case where the scribe line M′ is formed on the outer end surface 50b of the lid substrate wafer 50 during cutting step, and the cutting blade 70 is pressed from the outer end surface 40b of the base substrate wafer 40, the invention is not limited to this. For example, the scribe line M′ may be formed on the outer end surface 40b of the base substrate wafer 40, and the cutting blade 70 may be pressed from the outer end surface 50b of the lid substrate wafer 50.

In addition, the recess 3a may be formed on the base substrate wafer 40, and the recess 3a may be formed on each of the two wafers 40 and 50.

Furthermore, the first and second lasers are only examples and can be appropriately selected in accordance with the material.

In addition, although the bonding layer 23 needs to be formed to be continuous on the two wafers 40 and 50 in order to secure electrical conduction in the bonding step (S60), it is not always necessary to bond the two wafers 40 and 50 in a state where the bonding layer 23 is formed over the entire region of the bonding surfaces of the two wafers 40 and 50 as in the embodiment described above. That is, although the embodiment has been described for the case where the bonding layer 23 on the outline M is delaminated at once from the two wafers 40 and 50 in the trimming step (S94), a patterning step of removing the unnecessary bonding layer 23 in advance may be performed before the bonding step (S60). Specifically, as shown in FIG. 21, the bonding layer 23 on the outline M may be patterned before the bonding step (S60) so as to remove the bonding layer 23 at predetermined intervals so that the bonding layers 23 are only partially connected to each other.

In this way, by removing the unnecessary bonding layer 23 in advance before the bonding step (S60), it is possible to decrease the area of the bonding layer 23 delaminated by the first laser 87 in the trimming step (S94) after the bonding. Therefore, it is possible to shorten the time for the trimming step (S94) and to improve workability.

It is possible to increase the number of packages picked out as non-defective products and thus to improve yield.

What is claimed is:

1. A bonded glass cutting method of cutting a bonded glass, in which a plurality of glass substrates is bonded together on bonding surfaces thereof through a bonding material, along an intended cutting line, the method comprising:
a first laser irradiation step of emitting a first laser to irradiate a beam having the absorption wavelength of the bonding material along the intended cutting line to thereby delaminate the bonding material on the intended cutting line from the bonding surfaces;
a second laser irradiation step of emitting a second laser to irradiate a beam having the absorption wavelength of the bonded glass along the intended cutting line to thereby form a groove on one surface of the bonded glass; and
a cutting step of cutting the bonded glass along the intended cutting line by applying a breaking stress to the intended cutting line of the bonded glass.

2. The bonded glass cutting method according to claim 1,
wherein the bonding material is made of a conductive metallic material,
wherein the bonded glass has the plurality of glass substrates of which the bonding surfaces are anodically bonded to each other, and
wherein in the first laser irradiation step, the wavelength of the first laser is set to 532 nm.

3. The bonded glass cutting method according to claim 1,
wherein the glass substrate is formed of a soda-lime glass, and
wherein in the second laser irradiation step, the wavelength of the second laser is set to 266 nm.

4. The bonded glass cutting method according to claim 1,
wherein in the cutting step, the breaking stress is applied along the groove from the other surface of the bonded glass.

5. The bonded glass cutting method according to claim 1,
wherein the bonded glass is bonded by disposing the bonding material on only a part of the intended cutting line, and
wherein in the first laser irradiation step, the beam of the first laser is irradiated onto only the bonding material disposed on the intended cutting line.

6. A method of manufacturing a package which includes a plurality of glass substrates bonded to each other through a bonding material, and a cavity formed at an inner side of the plurality of glass substrates, and which is capable of sealing an electronic component in the cavity,
wherein the plurality of glass substrates is cut for each formation region of the package using the bonded glass cutting method according to claim 1.

7. A package which includes a plurality of glass substrates bonded to each other through a bonding material, and a cavity formed at an inner side of the plurality of glass substrates, and in which an electronic component is sealed in the cavity,
wherein the package is cut using the bonded glass cutting method according to claim 1, and
wherein a chamfered portion where the groove formed by the second laser is divided is provided on an outer peripheral portion of a surface of the package on a side where it is irradiated by the second laser.

8. A piezoelectric vibrator in which a piezoelectric vibrating reed is airtightly sealed in the cavity of the package according to claim 7.

9. An oscillator in which the piezoelectric vibrator according to claim 8 is electrically connected to an integrated circuit as an oscillating piece.

10. An electronic device in which the piezoelectric vibrator according to claim 8 is electrically connected to a clock section.

11. A radio-controlled timepiece in which the piezoelectric vibrator according to claim 8 is electrically connected to a filter section.
